(19) United States
(12) Patent Application Publication
(10) Pub. No.: US 2018/0097096 A1
(43) Pub. Date: Apr. 5, 2018

(54) SEMICONDUCTOR DEVICE

(71) Applicant: KABUSHIKI KAISHA TOSHIBA, Tokyo (JP)

(72) Inventors: Toru SUGIYAMA, Nonoichi (JP); Masako KODERA, Kanazawa (JP); Kunio TSUDA, Nonoichi (JP)

(73) Assignee: KABUSHIKI KAISHA TOSHIBA, Tokyo (JP)

(21) Appl. No.: 15/449,363

(22) Filed: Mar. 3, 2017

(30) Foreign Application Priority Data
Oct. 3, 2016 (JP) 2016-195380

(51) Int. Cl. H01L 29/778; H01L 29/20; H01L 29/205; H01L 29/423; H01L 29/36

(52) U.S. Cl. CPC H01L 29/7787; H01L 29/2003; H01L 29/36; H01L 29/42356; H01L 29/205

(57) ABSTRACT

A semiconductor device includes a first nitride semiconductor layer, a second nitride semiconductor layer provided on the first nitride semiconductor layer and having a bandgap larger than a bandgap of the first nitride semiconductor layer, a gate electrode provided on the first nitride semiconductor layer, a first electrode provided on the first nitride semiconductor layer and electrically connected to the first nitride semiconductor layer, a second electrode provided on the first nitride semiconductor layer, electrically connected to the first nitride semiconductor layer, and located between the first electrode and the second electrode, a first aluminum nitride layer that provided between the gate electrode and the second electrode, and provided on the second nitride semiconductor layer, and a second aluminum nitride layer provided on the first aluminum nitride layer. The first aluminum nitride layer is crystalline. The second aluminum nitride layer is non-crystalline.

### CROSS-REFERENCE TO RELATED APPLICATION

This application claims the benefit of and priority to Japanese Patent Application No. 2016-195380, filed Oct. 3, 2016, the entire contents of which are incorporated herein by reference.

### FIELD

Embodiments described herein relate generally to a semiconductor device.

### BACKGROUND

In a high electron mobility transistor (HEMT) using III-V compound semiconductors, a two-dimensional electron gas (2-DEG) is formed in a channel layer. Due to the two-dimensional electron gas, low on-resistance and high-speed switching are realized.

Structurally, the HEMT tends to be in a normally-on operation in which conduction occurs even when a voltage is not applied to a gate. However, from the viewpoint of safely operating a circuit in which the HEMT is incorporated, it is desirable to adopt a normally-off operation in which conduction does not occur unless a voltage is applied to a gate electrode.

### SUMMARY

In some embodiments according to one aspect, a semiconductor device including a first nitride semiconductor layer, a second nitride semiconductor layer provided on the first nitride semiconductor layer, and having a bandgap larger than a bandgap of the first nitride semiconductor layer, a gate electrode provided on the first nitride semiconductor layer, a first electrode provided on the first nitride semiconductor layer and electrically connected to the first nitride semiconductor layer, a second electrode provided on the first nitride semiconductor layer and electrically connected to the first nitride semiconductor layer, a first aluminum nitride layer provided between the gate electrode and the second electrode and provided on the second nitride semiconductor layer, and a second aluminum nitride layer provided on the first aluminum nitride layer. The gate electrode may be located between the first electrode and the second electrode. The first aluminum nitride layer may be crystalline. The second aluminum nitride layer may be non-crystalline.

Other aspects and embodiments of the disclosure are also encompassed. The foregoing summary and the following detailed description are not meant to restrict the disclosure to any particular embodiment but are merely meant to describe some embodiments of the disclosure.

### DESCRIPTION OF THE DRAWINGS

FIG. 1 is a schematic cross-sectional view of a semiconductor device according to some embodiments.

FIG. 2 is a schematic cross-sectional view of the semiconductor device which is being manufactured, according to some embodiments.

FIG. 3 is a schematic cross-sectional view of the semiconductor device which is being manufactured, according to some embodiments.

FIG. 4 is a schematic cross-sectional view of the semiconductor device which is being manufactured, according to some embodiments.

FIG. 5 is a schematic cross-sectional view of the semiconductor device which is being manufactured, according to some embodiments.

FIG. 6 is a schematic cross-sectional view of the semiconductor device which is being manufactured, according to some embodiments.

FIG. 7 is a schematic cross-sectional view of the semiconductor device which is being manufactured, according to some embodiments.

FIG. 8 is a diagram for describing operational effects of the semiconductor device according to some embodiments.

FIG. 9 is a diagram for describing operational effects of the semiconductor device according to some embodiments.

FIG. 10 is a diagram for describing operational effects of the semiconductor device according to some embodiments.

FIG. 11 is a diagram for describing operational effects of the semiconductor device according to some embodiments.

FIG. 12 is a schematic cross-sectional view of a semiconductor device according to some embodiments.

FIG. 13 is a schematic cross-sectional view of the semiconductor device which is being manufactured, according to some embodiments.

FIG. 14 is a schematic cross-sectional view of the semiconductor device which is being manufactured, according to some embodiments.

FIG. 15 is a schematic cross-sectional view of the semiconductor device which is being manufactured, according to some embodiments.

FIG. 16 is a schematic cross-sectional view of the semiconductor device which is being manufactured, according to some embodiments.

FIG. 17 is a schematic cross-sectional view of the semiconductor device which is being manufactured, according to some embodiments.

FIG. 18 is a schematic cross-sectional view of the semiconductor device which is being manufactured, according to some embodiments.

FIG. 19 is a schematic cross-sectional view of the semiconductor device which is being manufactured, according to some embodiments.

FIG. 20 is a schematic cross-sectional view of the semiconductor device which is being manufactured, according to some embodiments.

FIG. 21 is a schematic cross-sectional view of the semiconductor device which is being manufactured, according to some embodiments.

### DETAILED DESCRIPTION

An example embodiment provides a semiconductor device capable of realizing low on-resistance and a normally-off operation. In order for the HEMT to realize a normally-off operation, a cap layer may be provided between a gate electrode and a channel layer, a recess may be provided immediately below a gate electrode, an MIS (Metal Insulator Semiconductor) structure, and the like. It is desirable to realize a normally-off operation without sacrificing on-resistance.

In some embodiments, a normally-off operation can be realized without sacrificing on-resistance. According to some embodiments, a semiconductor device may include a first nitride semiconductor layer, a second nitride semiconductor layer provided on the first nitride semiconductor layer and having a bandgap larger than a bandgap of the first nitride semiconductor layer, a gate electrode provided on the first nitride semiconductor layer, a first electrode provided on the first nitride semiconductor layer and electrically connected to the first nitride semiconductor layer, a second electrode provided on the first nitride semiconductor layer and electrically connected to the first nitride semiconductor layer, a first aluminum nitride layer provided between the gate electrode and the second electrode and provided on the second nitride semiconductor layer, and a second aluminum nitride layer provided on the first aluminum nitride layer. The gate electrode may be located between the first electrode and the second electrode. The first aluminum nitride layer may be crystalline. The second aluminum nitride layer may be non-crystalline.

In the following description, the corresponding elements and the like are given the same reference signs described once will not be described repeatedly.

In the following description, “undoped” means that an impurity concentration is not more than 1×10¹⁵ cm⁻³.

In the following description, an upward direction of the drawing is described as “up” and a downward direction of the drawing as “down” in order to indicate a positional relation of components and the like. In the following description, note that concepts of “up” and “down” do not necessarily indicate a relation with a gravity direction. In the description of some embodiments, an element provided “on” another element can encompass cases where the former element is directly on (e.g., in physical contact with) the latter element, as well as cases where one or more intervening elements are located between the former element and the latter element.

An impurity concentration in a nitride semiconductor layer can be measured by, for example, a secondary ion mass spectrometry (SIMS). A relative level of an impurity concentration can also be determined from a relative level of a carrier concentration obtained by, for example, a scanning capacitance microscopy (SCM). In some embodiments, a distance between an electrode and an impurity region can be obtained from a composite image of an SCM image and an AFM (Atomic Force Microscopy) image.

A semiconductor device according to some embodiments may include a first nitride semiconductor layer, a second nitride semiconductor layer provided on the first nitride semiconductor layer and having a bandgap larger than a bandgap of the first nitride semiconductor layer, a gate electrode provided on the first nitride semiconductor layer, a first electrode provided on the first nitride semiconductor layer and electrically connected to the first nitride semiconductor layer, a second electrode provided on the first nitride semiconductor layer and electrically connected to the first nitride semiconductor layer, a first aluminum nitride layer provided between the gate electrode and the second electrode and provided on the second nitride semiconductor layer, and a second aluminum nitride layer provided on the first aluminum nitride layer. The first aluminum nitride layer may be crystalline. The second aluminum nitride layer may be non-crystalline. The gate electrode may be located between the first electrode and the second electrode.

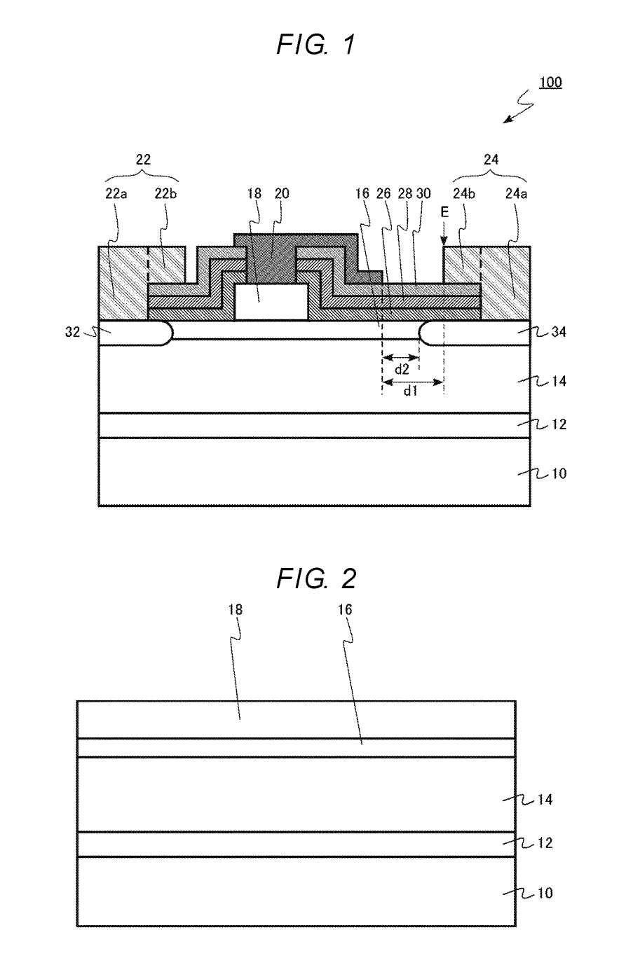

FIG. 1 is a schematic cross-sectional view of the semiconductor device according to some embodiments. The semiconductor device according to some embodiments may be an HEMT using III-V compound semiconductors.

As illustrated in FIG. 1, in some embodiments, an HEMT 100 (semiconductor device) includes a substrate 10, a buffer layer 12, a channel layer 14 (first nitride semiconductor layer), a barrier layer 16 (second nitride semiconductor layer), a p-type layer 18 (third nitride semiconductor layer), a gate electrode 20, a source electrode 22 (first electrode), a drain electrode 24 (second electrode), a first aluminum nitride layer 26, a second aluminum nitride layer 28, an aluminum oxide layer 30, a first n-type impurity region 32, and a second n-type impurity region 34 (semiconductor region).

In some embodiments, the substrate 10 is formed of silicon whose a surface has a plane orientation of (111), for example. Apart from the silicon, for example, sapphire or silicon carbide is also applicable.

In some embodiments, the buffer layer 12 is provided on the substrate 10. In some embodiments, the buffer layer 12 has a function of relaxing lattice mismatch between the substrate 10 and the channel layer 14. In some embodiments, the buffer layer 12 is formed of, for example, aluminum nitride and aluminum gallium nitride.

In some embodiments, the channel layer 14 is provided on the buffer layer 12. The channel layer 14 is also called as an electron transit layer.

In some embodiments, the channel layer 14 is formed of undoped AlₓGa₁₋ₓN (0≦X<1), for example. In some embodiments, the channel layer 14 is formed of undoped gallium nitride (GaN), for example. In some embodiments, the channel layer 14 has a thickness of 0.1 μm or greater and 10 μm or less, for example.

In some embodiments, the barrier layer 16 is provided on the channel layer 14. The barrier layer 16 is also called as an electron supply layer. In some embodiments, the barrier layer 16 has a bandgap larger than that of the channel layer 14.

In some embodiments, the barrier layer 16 having a large bandgap has a lattice constant different from that of the channel layer 14. For this reason, distortion may occur and polarization may be caused by a piezoelectric effect. By an internal electric field caused by the polarization, the band of the channel layer 14 may be pushed down, and a 2-DEG may be formed as an inversion layer.

The barrier layer 16 is formed of undoped Al_{y}Ga_{1-y}N (0<Y≦1, X<Y), for example. The barrier layer 16 is formed of undoped aluminum gallium nitride, for example. In some embodiments, the barrier layer 16 is formed of undoped Al_{0.2}Ga_{0.8}N, for example. In some embodiments, the thickness of the barrier layer 16 is, for example, 1 nm or greater and 50 nm or less.

In some embodiments, a heterojunction interface is formed between the channel layer 14 and the barrier layer 16. In some embodiments, a 2-DEG is formed in the channel layer 14 by a polarization charge of the heterojunction interface. The 2-DEG has high electron mobility, and can allow low on-resistance and high-speed switching during device operation.

In some embodiments, the p-type layer 18 is provided on the barrier layer 16. In some embodiments, the p-type layer 18 is provided between the source electrode 22 and the drain electrode 24.

In some embodiments, the p-type layer 18 may raise a band of the channel layer 14 provided below the p-type layer 18 and raise a threshold value of the HEMT 100. The p-type layer 18 is also called as a cap layer.

The p-type layer 18 is formed of, for example, Al_{z}Ga_{1-z}N (0≦Z<1, Z<Y) containing a p-type impurity. In some embodiments, the p-type layer 18 is formed of, for example, p-type gallium nitride (GaN).

The p-type impurity is magnesium (Mg), for example. In some embodiments, the p-type impurity has an impurity concentration of not less than 1×10¹⁹ cm⁻³ and not more than 1×10²¹ cm⁻³.

The p-type layer 18 has a thickness of 10 nm or greater and 50 nm or less, for example.

In some embodiments, the gate electrode 20 is provided on the p-type layer 18. In some embodiments, the gate electrode 20 is provided between the source electrode 22 and the drain electrode 24.

In some embodiments, the gate electrode 20 has a gate field-plate structure. That is, the gate electrode 20 may have a structure in which an upper portion thereof extends toward the drain electrode 24. Since the gate electrode 20 has the gate field-plate structure, electric field strength may be relaxed when the HEMT 100 is turned off, and reliability of the HEMT 100 can be improved.

The gate electrode 20 is, for example, a metal electrode. The gate electrode 20 is formed of, for example, titanium nitride.

In some embodiments, Ohmic contact or Schottky contact is formed between the gate electrode 20 and the p-type layer 18.

In some embodiments, the first aluminum nitride layer 26 is provided between the gate electrode 20 and the drain electrode 24. In some embodiments, the first aluminum nitride layer 26 is provided on the barrier layer 16. In some embodiments, the first aluminum nitride layer 26 is in contact with the barrier layer 16.

In some embodiments, the first aluminum nitride layer 26 is crystalline. The first aluminum nitride layer 26 is, for example, a monocrystalline layer. In some embodiments, it is possible to identify whether the first aluminum nitride layer 26 is crystalline, using a transmission electron microscope (TEM), for example.

In some embodiments, the first aluminum nitride layer 26 may be a material containing aluminum nitride as a main component, and may contain other materials as an accessory component. In some embodiments, the first aluminum nitride layer 26 has a thickness of 1 nm or greater and 10 nm or less, for example.

In some embodiments, the first aluminum nitride layer 26 is provided between the gate electrode 20 and the source electrode 22.

In some embodiments, the second aluminum nitride layer 28 is provided between the gate electrode 20 and the drain electrode 24. In some embodiments, the second aluminum nitride layer 28 is provided on the first aluminum nitride layer 26. In some embodiments, the second aluminum nitride layer 28 is in contact with the first aluminum nitride layer 26.

In some embodiments, the second aluminum nitride layer 28 is non-crystalline (amorphous). In some embodiments, it is possible to identify whether the second aluminum nitride layer 28 is non-crystalline, using a transmission electron microscope, for example.

In some embodiments, the second aluminum nitride layer 28 may be a material containing aluminum nitride as a main component, and may contain other materials as an accessory component. In some embodiments, the second aluminum nitride layer 28 has a thickness of 1 nm or greater and 10 nm or less, for example.

In some embodiments, the second aluminum nitride layer 28 is provided between the gate electrode 20 and the source electrode 22.

In some embodiments, the sum of the thickness of the first aluminum nitride layer 26 and the thickness of the second aluminum nitride layer 28 is, for example, 10 nm or greater.

In some embodiments, the aluminum oxide layer 30 is provided between the gate electrode 20 and the drain electrode 24. In some embodiments, the aluminum oxide layer 30 is provided on the second aluminum nitride layer 28. In some embodiments, the aluminum oxide layer 30 is in contact with the second aluminum nitride layer 28.

In some embodiments, the aluminum oxide layer 30 may have a function of preventing oxidation of the second aluminum nitride layer 28. The aluminum oxide layer 30 has a thickness of 1 nm or greater and 10 nm or less, for example.

In some embodiments, the aluminum oxide layer 30 is provided between the gate electrode 20 and the source electrode 22.

In some embodiments, the first n-type impurity region 32 is provided between the channel layer 14 and the source electrode 22. In some embodiments, the first n-type impurity region 32 is a nitride semiconductor containing an n-type impurity.

For example, the first n-type impurity region 32 is formed of n-type Al_{w}Ga_{1-w}N (0≦W≦1). The first n-type impurity region 32 is formed of, for example, n-type aluminum gallium nitride. Apart of the first n-type impurity region 32 is formed of n-type gallium nitride, for example.

The n-type impurity of the first n-type impurity region 32 is, for example, silicon (Si). In some embodiments, the n-type impurity of the first n-type impurity region 32 has an impurity concentration higher than the n-type impurity of the barrier layer 16.

The first n-type impurity region 32 has a thickness thicker than that of the barrier layer 16, for example.

In some embodiments, the second n-type impurity region 34 is provided between the channel layer 14 and the drain electrode 24. In some embodiments, the second n-type impurity region 34 is a nitride semiconductor containing an n-type impurity.

For example, the second n-type impurity region 34 is formed of n-type Al_{w}Ga_{1-w}N (0≦W≦1). The second n-type impurity region 34 is formed of, for example, n-type aluminum gallium nitride. A part of the second n-type impurity region 34 is formed of n-type gallium nitride, for example.

The n-type impurity of the second n-type impurity region 34 is, for example, silicon (Si). In some embodiments, the n-type impurity of the second n-type impurity region 34 has an impurity concentration higher than the n-type impurity of the barrier layer 16.

In some embodiments, the second n-type impurity region 34 has a thickness thicker than a thickness of the barrier layer 16, for example.

In some embodiments, the source electrode 22 is provided on the channel layer 14. In some embodiments, the source electrode 22 is provided on the first n-type impurity region 32. In some embodiments, the source electrode 22 is provided in contact with the first n-type impurity region 32. In some embodiments, Ohmic contact is formed between the source electrode 22 and the first n-type impurity region 32.

For example, the source electrode 22 is a metal electrode. The source electrode 22 has a stacked structure of titanium (Ti)/aluminum (Al)/titanium (Ti), for example.

In some embodiments, the source electrode 22 includes a first region 22a and a second region 22b. In some embodiments, the second region 22b is provided around the first region 22a on an upper part of the source electrode 22. The second region 22b is a so-called fringe. In some embodiments, the second region 22b is closer to the gate electrode 20 than the first region 22a is to the gate electrode 20.

In some embodiments, the first region 22a is in contact with the first n-type impurity region 32. In some embodiments, between the channel layer 14 and the second region 22b, the first aluminum nitride layer 26, the second aluminum nitride layer 28, and the aluminum oxide layer 30 are located.

In some embodiments, the first region 22a and the second region 22b may be formed of different materials.

In some embodiments, the drain electrode 24 is provided on the channel layer 14. In some embodiments, the drain electrode 24 is provided on the second n-type impurity region 34. In some embodiments, the drain electrode 24 is provided in contact with the second n-type impurity region 34. In some embodiments, Ohmic contact is formed between the drain electrode 24 and the second n-type impurity region 34.

In some embodiments, the drain electrode 24 is a metal electrode, for example. The drain electrode 24 has a stacked structure of titanium (Ti)/aluminum (Al)/titanium (Ti), for example.

In some embodiments, the drain electrode 24 includes a first region 24a and a second region 24b. In some embodiments, the second region 24b is provided around the first region 24a on an upper part of the drain electrode 24. The second region 24b is a so-called fringe. In some embodiments, the second region 24b is closer to the gate electrode 20 than the first region 24a is to the gate electrode 20.

In some embodiments, the first region 24a is in contact with the second n-type impurity region 34. In some embodiments, between the channel layer 14 and the second region 24b, the first aluminum nitride layer 26, the second aluminum nitride layer 28, and the aluminum oxide layer 30 are located.

In some embodiments, the first region 24a and the second region 24b may be formed of different materials.

In some embodiments, the second n-type impurity region 34 is located between an end (E in FIG. 1) of the second region 24b on a side of the gate electrode 20 and the channel layer 14. In some embodiments, a horizontal distance (d1 in FIG. 1) between the gate electrode 20 and the second region 24b is longer than a horizontal distance (d2 in FIG. 1) between the gate electrode 20 and the second n-type impurity region 34.

A distance between the source electrode 22 and the drain electrode 24 is, for example, 3 μm or longer and 80 μm or shorter.

An interlayer insulating layer (not illustrated) is formed on the gate electrode 20 and the aluminum oxide layer 30. For example, the interlayer insulating layer is a silicon nitride layer. For example, a wiring layer is formed on the interlayer insulating layer, the wiring layer being connected to the gate electrode 20, the source electrode 22, and the drain electrode 24.

In some embodiments, for example, an element isolation area may be provided in the channel layer 14 interposed between the HEMT 100 and an adjacent element, the element isolation area being formed by ion implantation of argon.

An example of a manufacturing method of the semiconductor device according to some embodiments will be described below. FIGS. 2 to 7 are schematic cross-sectional views of the semiconductor device which is being manufactured in the manufacturing method of the semiconductor device according to some embodiments.

The manufacturing method of the semiconductor device according to some embodiments includes performing dry etching on the nitride semiconductor layer. In some embodiments, a water-soluble layer may be formed on a surface of the nitride semiconductor layer exposed after the dry etching. In some embodiments, the water-soluble layer may be removed with pure water. In some embodiments, the surface of the nitride semiconductor layer may be cleaned with an acid solution or an alkaline solution. The manufacturing method of the semiconductor device according to some embodiments may include a post-treatment after the dry etching.

First, a substrate 10, for example, a silicon substrate is prepared. Next, for example, a buffer layer 12 is grown on the silicon substrate through epitaxial growth.

Subsequently, in some embodiments, undoped gallium nitride, aluminum gallium nitride, and p-type gallium nitride are grown on the buffer layer 12 through epitaxial growth to form a channel layer 14, a barrier layer 16, and a p-type layer 18, respectively (see FIG. 2).

In some embodiments, the buffer layer 12, the channel layer 14, the barrier layer 16, and the p-type layer 18 are formed by metal oxide chemical vapor deposition (MOCVD), for example.

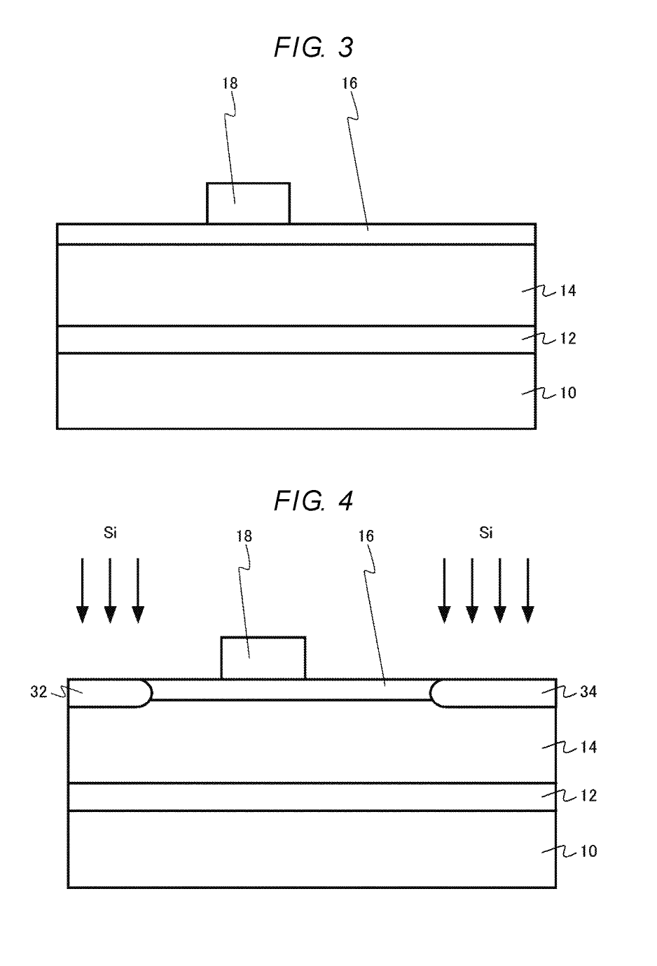

Thereafter, in some embodiments, a part of the p-type layer 18 is selectively removed (see FIG. 3). The p-type layer is removed by patterning of a photoresist according to photolithography and dry etching, for example.

For example, the dry etching is performed by ICP-RIE (Inductive Coupled Plasma-Reactive Ion Etching). From the viewpoint of reducing etching damage, it is desirable to load a DC bias with low power of 100 W or less at the time of etching.

In some embodiments, after the dry etching, a post-treatment is performed. First, in some embodiments, a water-soluble reaction layer is formed on the surface of the barrier layer 16. The water-soluble reaction layer is an example of a water-soluble layer. One example method of forming the water-soluble reaction layer is to use a gas containing fluorine or chlorine as an etching gas for the dry etching. A gas containing both of fluorine and chlorine may be used as the etching gas.

Thereafter, in some embodiments, the surface of the barrier layer 16 is exposed under an oxygen atmosphere. For example, the surface is exposed under an oxygen or ozone atmosphere in an ashing apparatus.

In some embodiments, fluorine or chlorine remaining on the surface of the barrier layer 16 may react with oxygen, and the water-soluble reaction layer may be formed. In some embodiments, the water-soluble reaction layer may have a thickness of 2 nm or less, for example.

In some embodiments, the water-soluble reaction layer may contain from 10 to 20 atomic % of fluorine or chlorine. In some embodiments, the water-soluble reaction layer may contain from 10 to 20 atomic % of oxygen.

Subsequently, in some embodiments, the surface of the barrier layer 16 may be cleaned with pure water. In some embodiments, the cleaning with pure water may be performed at room temperature for five minutes or less, for example. In some embodiments, the water-soluble reaction layer is removed by cleaning with pure water.

Next, in some embodiments, cleaning may be performed using an acid solution or an alkaline solution. In some embodiments, the acid solution may have a value of from pH 1 to pH 4, for example. In some embodiments, the alkaline solution may have a value of from pH 9 to pH 14, for example.

In the case of using the acid solution, for example, the solution contains at least one of hydrochloric acid, sulfuric acid, and hydrofluoric acid. In the case of using the alkaline solution, for example, the solution contains at least one of ammonia, tetramethylammonium hydroxide, methanolamine, triethylenetetraamine, and choline.

In some embodiments, the acid solution or the alkaline solution may contain an oxidizing agent. The oxidizing agent may include hydrogen peroxide, ozone water, and ammonium persulfate aqueous solution, for example.

Subsequently, in some embodiments, a first n-type impurity region 32 and a second n-type impurity region 34 are formed in a region in which the source electrode 22 and the drain electrode 24 are formed later (see FIG. 4). In some embodiments, the first n-type impurity region 32 and the second n-type impurity region 34 are formed by patterning of a photoresist according to photolithography and ion implantation of silicon, for example. The ion implantation may be performed under conditions of 40 keV and 5×10¹⁵ cm⁻², for example.

In some embodiments, silicon is introduced onto the barrier layer 16 and the channel layer 14. In some embodiments, after the photoresist is removed, and annealing may be performed, for example, at a temperature of from 700° C. to 900° C. under a non-oxidizing atmosphere to activate silicon.

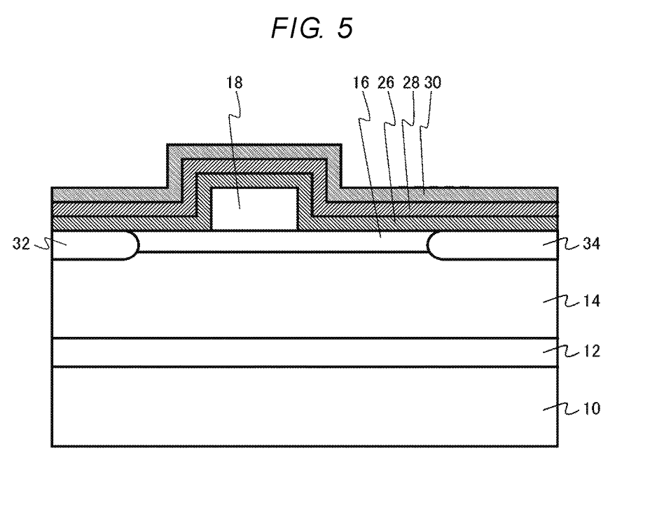

Subsequently, in some embodiments, a first aluminum nitride layer 26, a second aluminum nitride layer 28, and an aluminum oxide layer 30 are formed on the barrier layer 16 and the p-type layer 18 (see FIG. 5). In some embodiments, the first aluminum nitride layer 26, the second aluminum nitride layer 28, and the aluminum oxide layer 30 may be successively formed by ALD (Atomic Layer Deposition), for example.

First, in some embodiments, the first aluminum nitride layer 26 having crystalline properties is formed on the barrier layer 16. The first aluminum nitride layer 26 is a monocrystalline layer, for example. Next, in some embodiments, the second aluminum nitride layer 28 having non-crystalline properties is formed on the first aluminum nitride layer 26 by changing deposition conditions for aluminum nitride. For example, the second aluminum nitride layer 28 may be formed at a lower temperature compared to the first aluminum nitride layer 26.

In some embodiments, the first aluminum nitride layer 26 and the second aluminum nitride layer 28 may be formed at a temperature lower than 600° C., for example.

Subsequently, in some embodiments, the aluminum oxide layer 30 is formed on the second aluminum nitride layer 28.

Next, in some embodiments, an opening is formed in the first aluminum nitride layer 26, the second aluminum nitride layer 28, and the aluminum oxide layer 30 which are formed on the p-type layer 18. In some embodiments, the opening may be formed by patterning of a photoresist according to photolithography and dry etching, for example.

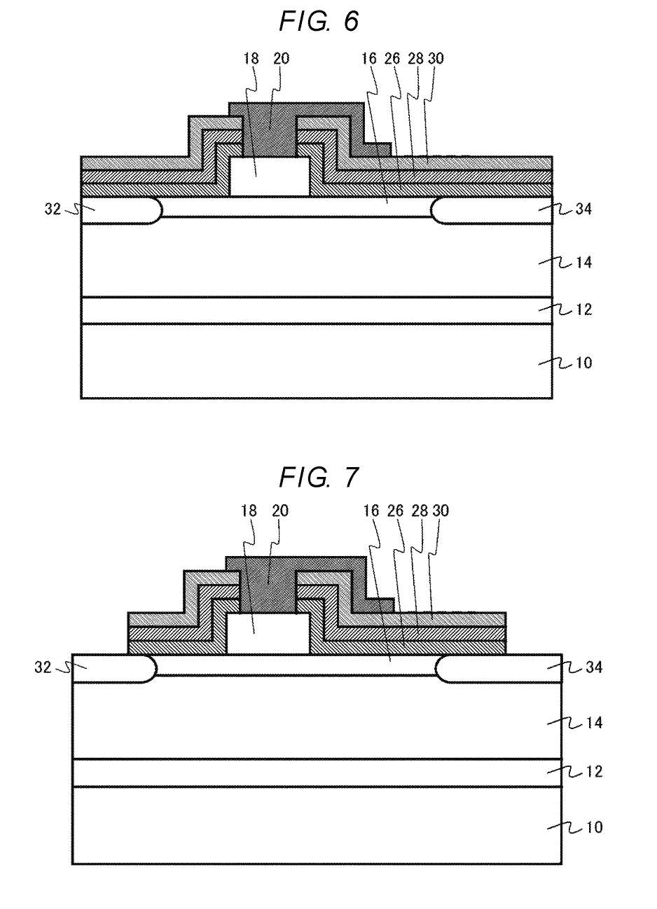

Subsequently, in some embodiments, a gate electrode 20 is formed in a region including the opening (see FIG. 6). In some embodiments, the gate electrode 20 may be formed by deposition of titanium nitride according to sputtering, patterning of a photoresist according to photolithography, and dry etching.

Subsequently, in some embodiments, an opening is formed in the first aluminum nitride layer 26, the second aluminum nitride layer 28, and the aluminum oxide layer 30 which are formed on the first n-type impurity region 32 and the second n-type impurity region 34 (see FIG. 7).

Next, in some embodiments, a source electrode 22 and a drain electrode 24 may be formed in a region including the opening. In some embodiments, the source electrode 22 and the drain electrode 24 may be formed by deposition of a stacked film of titanium (Ti)/aluminum (Al)/titanium (Ti) according to sputtering, patterning of a photoresist according to photolithography, and dry etching, for example.

By the above-described manufacturing method, the HEMT 100 is manufactured as illustrated in FIG. 1.

Operational effects of the semiconductor device according to some embodiments will be described below.

From the viewpoint of safely operating a circuit in which the HEMT is incorporated, it is desirable to adopt a normally-off operation in which conduction does not occur unless a voltage is applied to the gate electrode. In the HEMT 100 according to some embodiments, the p-type layer 18 is provided, and thus a normally-off operation is realized.

That is, in some embodiments, a potential of the channel layer 14 may be raised by the p-type layer 18, and the channel layer 14 immediately below the gate electrode 20 may be depleted. Accordingly, the HEMT 100 realizes the normally-off operation.

Depending on an application of a circuit in which the HEMT is incorporated, in some embodiments, a high positive threshold voltage, for example, a threshold voltage of 1 V or higher may be realized. In some embodiments, in order to further raise the threshold voltage, the thickness of the barrier layer may be made thin, thereby reducing a piezoelectric polarization effect and reducing a density of the 2-DEG induced in the channel layer 14. However, when the density of the 2-DEG becomes lower, the on-resistance may increase.

In the HMT 100 according to some embodiments, the thickness of the barrier layer 16 may be thinned to realize the high positive threshold voltage. On the other hand, in some embodiments, since the first aluminum nitride layer 26 and the second aluminum nitride layer 28 are provided between the gate electrode 20 and the source electrode 22 and between the gate electrode 20 and the drain electrode 24, the density of the 2-DEG may increase in a region other than the region immediately below the gate electrode 20.

That is, the density of the 2-DEG may increase due to spontaneous polarization of the first aluminum nitride layer 26 and the second aluminum nitride layer 28. In some embodiments, the density of the 2-DEG may become larger as the thickness of the first aluminum nitride layer 26 and the second aluminum nitride layer 28 becomes thicker.

In some embodiments, from the viewpoint of increasing the spontaneous polarization, it is desirable that the aluminum nitride layer is crystalline, and particularly a monocrystal. For this reason, the first aluminum nitride layer 26 may be formed to be a crystalline layer in some embodiments.

However, when a crystalline layer, particularly, a monocrystalline layer is deposited on the barrier layer 16, cracks may occur in the aluminum nitride layer due to stress of the film. If the cracks occur in the aluminum nitride layer, reliability failure may occur.

Further, when the crystalline layer is a polycrystalline layer, a leak current may flow through grain boundaries. For example, the grain boundaries serve as a path of the gate leak current, and thus reliability failure may occur.

In some embodiments, the second aluminum nitride layer 28 may be formed to be a non-crystalline layer from the viewpoint of suppressing the occurrence of the reliability failure. When the second aluminum nitride layer 28 is the non-crystalline layer, the occurrence of the cracks may be suppressed. In addition, the leak current may be suppressed when the second aluminum nitride layer 28 is the non-crystalline layer.

In some embodiments, the barrier layer 16 may be an undoped aluminum nitride layer having a thickness of 15 nm, the p-type layer 18 may be a gallium nitride layer doped with magnesium of 1×10²⁰ cm⁻³ and having a thickness of 40 nm, the first aluminum nitride layer 26 may be a monocrystalline layer having a thickness of 5 nm, and the second aluminum nitride layer 28 may be a non-crystalline layer having a thickness of 5 nm. With this configuration, on-resistance may be reduced by approximately 30% compared to a case where the first aluminum nitride layer 26 and the second aluminum nitride layer 28 are not provided. In some embodiments, a high threshold voltage of 1.3 V may be realized.

From the viewpoint of increasing the threshold voltage, in some embodiments, the thickness of the barrier layer 16 is desirably 15 nm or less, more desirably 10 nm or less, and further more desirably 5 nm or less.

From the viewpoint of improving the density of the 2-DEG, in some embodiments, it is desirable that the first aluminum nitride layer 26 be a monocrystalline layer. From the viewpoint of improving the density of the 2-DEG, in some embodiments, the thickness of the first aluminum nitride layer 26 is desirably 1 nm or greater, and more desirably 3 nm or greater. From the viewpoint of suppressing the occurrence of the cracks, in some embodiments, the thickness of the first aluminum nitride layer 26 is desirably 10 nm or less, and more desirably 5 nm or less.

From the viewpoint of improving the density of the 2-DEG, in some embodiments, the sum of the thickness of the first aluminum nitride layer 26 and the thickness of the second aluminum nitride layer 28 is desirably 10 nm or greater, and more desirably 15 nm or greater. From the viewpoint of suppressing the occurrence of the cracks, in some embodiments, the sum of the thickness of the first aluminum nitride layer 26 and the thickness of the second aluminum nitride layer 28 is desirably 30 nm or less, and more desirably 20 nm or less.

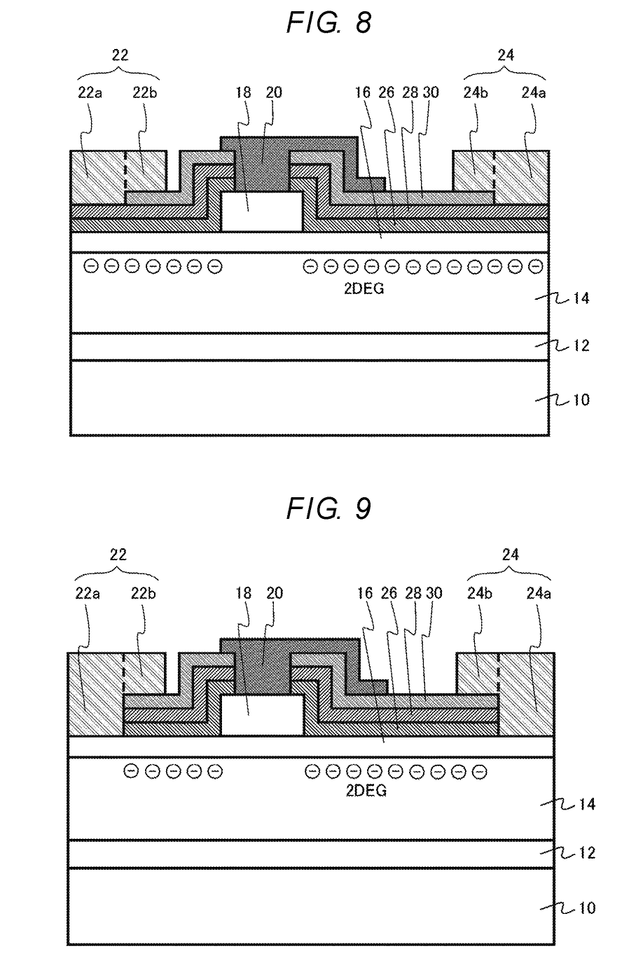

The description will be given below with respect to a structure of the source electrode 22 and the drain electrode 24 in the HEMT 100 according to some embodiments. FIGS. 8 to 11 are diagrams for describing operational effects of the semiconductor device according to some embodiments.

Aluminum nitride has a bandgap larger than a bandgap of aluminum gallium nitride or gallium nitride. For this reason, as illustrated in FIG. 8, when the source electrode 22 and the drain electrode 24 are formed on the second aluminum nitride layer 28, it is difficult to form ohmic contact. Accordingly, contact resistance of the source electrode 22 and the drain electrode 24 becomes higher, and on-resistance increases.

Therefore, in some embodiments, as illustrated in FIG. 9, the source electrode 22 and the drain electrode 24 are formed on the barrier layer 16. In this case, since the first aluminum nitride layer 26 and the second aluminum nitride layer 28 are not present, the density of the 2-DEG may be lowered under the source electrode 22 and the drain electrode 24. Therefore, resistance becomes higher between the 2-DEG and the source electrode 22 and between the 2-DEG and the drain electrode 24, and on-resistance increases.

As illustrated in FIG. 1, the HEMT 100 according to some embodiments includes the first n-type impurity region 32 provided below the source electrode 22 and the second n-type impurity region 34 provided below the drain electrode 24, the first n-type impurity region 32 and the second n-type impurity region 34 having low resistance. Accordingly, resistance is reduced between the 2-DEG and the source electrode 22 and between the 2-DEG and the drain electrode 24. Therefore, the on-resistance is reduced.

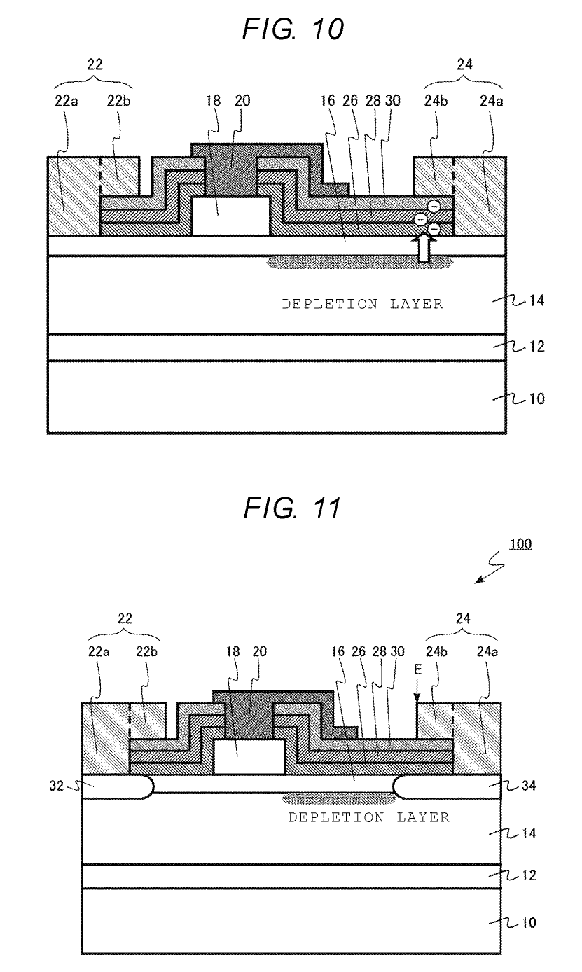

As illustrated in FIG. 10, in some embodiments, the source electrode 22 and the drain electrode 24 include fringes having a wider width than the opening by reason of a manufacturing process. In FIG. 10, the fringes are the second region 22b and the second region 24b.

As illustrated in FIG. 10, in some embodiments, when a depletion layer extends to a lower part of the fringe of the drain electrode 24 during the turning-off of the HEMT, electrons may be trapped under the fringe by an electric field generated between the fringe and the depletion layer. The HEMT enters a so-called current collapse state where the 2-DEG decreases due to Coulomb action of the trapped electrons, on-resistance may increase, and thus reliability may decrease.

In the HEMT 100 according to some embodiments, the second n-type impurity region 34 is located between the end (E in FIG. 1) of the second region 24b of the drain electrode 24 on the side of the gate electrode 20 and the channel layer 14. In some embodiments, the second n-type impurity region 34 exists immediately below the end of the fringe of the drain electrode 24.

Accordingly, in some embodiments, as illustrated in FIG. 11, during the turning-off of the HEMT 100, the extension of the depletion layer is stopped at the end of the second n-type impurity region 34 on the side of the gate electrode 20, and the depletion layer does not extend to the lower part of the fringe of the drain electrode 24. Therefore, the electrons are prevented from be trapped below the fringe. Accordingly, the increase in on-resistance is suppressed, and thus reliability of the HEMT 100 is improved.

In some embodiments, since the increase in on-resistance is suppressed as described above even when the depletion layer reaches the drain electrode 24, the distance between the gate electrode 20 and the drain electrode 24 can be narrowed. Therefore, the on-resistance of the HEMT 100 can be reduced. In addition, it is possible to reduce the chip size, and to reduce manufacturing costs of the HEMT 100.

Operational effects of the manufacturing method according to some embodiments will be described below.

When the nitride semiconductor layer is processed by dry etching, a damage layer may be formed on the surface of the nitride semiconductor layer exposed by the dry etching. The damage layer may be formed by a surface roughness or defect which is caused by dry etching, a composition change of the nitride semiconductor layer, and implantation or residue of etching gas components into the nitride semiconductor layer.

When the damage layer remains on the nitride semiconductor layer, device characteristics may be deteriorated. For example, charges are trapped in the damage layer, and thus the device characteristics fluctuate. For this reason, it is desirable to remove the damage layer.

However, if the removal amount of damage layer varies when the damage layer is removed, the variation in the removal amount may deteriorate the device characteristics. For example, the damage layer formed on the surface of the barrier layer 16 may be removed during etching of the p-type layer 18 according to some embodiments. In this case, if the removal amount of damage layer varies, the thickness of the barrier layer 16 to be etched at the time of the removal of the damage layer may vary. The variation in the thickness of the barrier layer 16 may lead to variations in the density of the 2-DEG, that is, variations in the on-resistance or the threshold voltage.

In the manufacturing method according to some embodiments, the damage layer on the surface of the barrier layer 16 is removed by the formation of the water-soluble reaction layer, the removal of the water-soluble reaction layer with pure water, and the cleaning of the surface of the barrier layer using the acid solution or the alkaline solution. By the post-treatment after the dry etching, the damage layer on the surface of the barrier layer 16 can be removed with good controllability. For example, it is possible to sufficiently remove the damage layer while suppressing the amount of the barrier layer 16, to be etched together with the removal of the damage layer, to 2 nm or less.

Table 1 indicates the effect of the manufacturing method according to some embodiments. A concentration ratio (ratio of Al to Ga (Al/Ga)) of aluminum and gallium in an aluminum gallium nitride layer changes due to etching damage of the dry etching. In Table 1, Comparative Example 1 indicates a ratio of Al to Ga (Al/Ga) in the aluminum gallium nitride layer which is not exposed by the dry etching, Comparative Example 2 indicates a ratio of Al to Ga (Al/Ga) in the aluminum gallium nitride layer which is not subjected to the post-treatment according to some embodiments after the dry etching, and Example indicates a ratio of Al to Ga (Al/Ga) in the aluminum gallium nitride layer which is subjected to the post-treatment according to some embodiments after the dry etching.

TABLE 1

| | Ratio of Al to Ga (Al/Ga) |
|---|---|
| Comparative Example 1 | 0.48 |
| Comparative Example 2 | 0.64 |
| Example | 0.54 |

As is apparent from Table 1, according to Example, it is found that the ratio of Al to Ga (Al/Ga) is closer to that of Comparative Example 1 compared to Comparative Example 2 and the damage layer is effectively removed depending on the change in the ratio of Al to Ga (Al/Ga). In Example, the amount of the aluminum gallium nitride layer to be etched together with the removal of the damage layer is 2 nm or less.

According to the manufacturing method of some embodiments, it is possible to effectively remove the damage layer while performing the etching of the nitride semiconductor layer with a small amount after the dry etching. Accordingly, it is possible to prevent deterioration in characteristics of the HEMT 100.

From the viewpoint of effectively removing the damage layer, in some embodiments, the acid solution desirably has a value of from pH 1 to pH 4. In some embodiments, the acid solution desirably contains at least one of hydrochloric acid, sulfuric acid, and hydrofluoric acid therein.

From the same viewpoint, in some embodiments, the alkaline solution desirably has a value of from pH 9 to pH 14. In some embodiments, the alkaline solution desirably contains at least one of ammonia, tetramethylammonium hydroxide, methanolamine, triethylenetetraamine, and choline therein.

From the viewpoint of effectively removing the damage layer, in some embodiments, the acid solution or the alkaline solution desirably contains an oxidizing agent.

In some embodiments like those illustrated in FIGS. 1-11, the HEMT 100 is capable of realizing the low on-resistance and the normally-off operation, thereby realizing improved reliability of the HEMT 100. Further, the HEMT 100 can be realized by which the chip size is reduced and the manufacturing costs are reduced.

A semiconductor device of some embodiments is different from that of the embodiments illustrated in FIGS. 1-11 in that a gate insulation layer is provided. Hereinafter, the same descriptions as those of the embodiments illustrated in FIGS. 1-11 will be omitted.

FIG. 12 is a schematic cross-sectional view of the semiconductor substrate according to some embodiments. The semiconductor device according to some embodiments is an HEMT using III-V compound semiconductors.

As illustrated in FIG. 12, in some embodiments, an HEMT 200 (semiconductor device) includes a substrate 10, a buffer layer 12, a channel layer 14 (first nitride semiconductor layer), a barrier layer 16 (second nitride semiconductor layer), a gate electrode 20, a source electrode 22 (first electrode), a drain electrode 24 (second electrode), a first aluminum nitride layer 26, a second aluminum nitride layer 28, a gate insulation layer 40, a first n-type impurity region 32, and a second n-type impurity region 34 (semiconductor region).

In some embodiments, the gate insulation layer 40 is provided between the barrier layer 16 and the gate electrode 20. In some embodiments, a part of the gate insulation layer 40 is provided in contact with the barrier layer 16. In some embodiments, another part of the gate insulation layer 40 is provided on the second aluminum nitride layer 28 so as to be in contact with the second aluminum nitride layer 28.

In some embodiments, the gate insulation layer 40 suppresses a gate leak current of the HEMT 200. The gate insulation layer 40 is formed of silicon oxide, for example. The gate insulation layer 40 has a thickness of 5 nm or greater and 30 nm or less, for example.

In some embodiments, the gate electrode 20 is provided on the gate insulation layer 40. In some embodiments, the gate electrode 20 is provided between the source electrode 22 and the drain electrode 24.

In some embodiments, the gate electrode 20 has a gate field-plate structure. That is, the gate electrode 20 has a structure in which an upper portion thereof extends toward the drain electrode 24.

The gate electrode 20 is, for example, a metal electrode. The gate electrode 20 is formed of, for example, titanium nitride.

In some embodiments, the second n-type impurity region 34 is located between an end (E in FIG. 12), on a side of the gate electrode 20, of the second region 24b of the drain electrode 24 and the channel layer 14. In some embodiments, a horizontal distance (d1 in FIG. 12) between the gate electrode 20 and the second region 24b is longer than a horizontal distance (d2 in FIG. 12) between the gate electrode 20 and the second n-type impurity region 34.

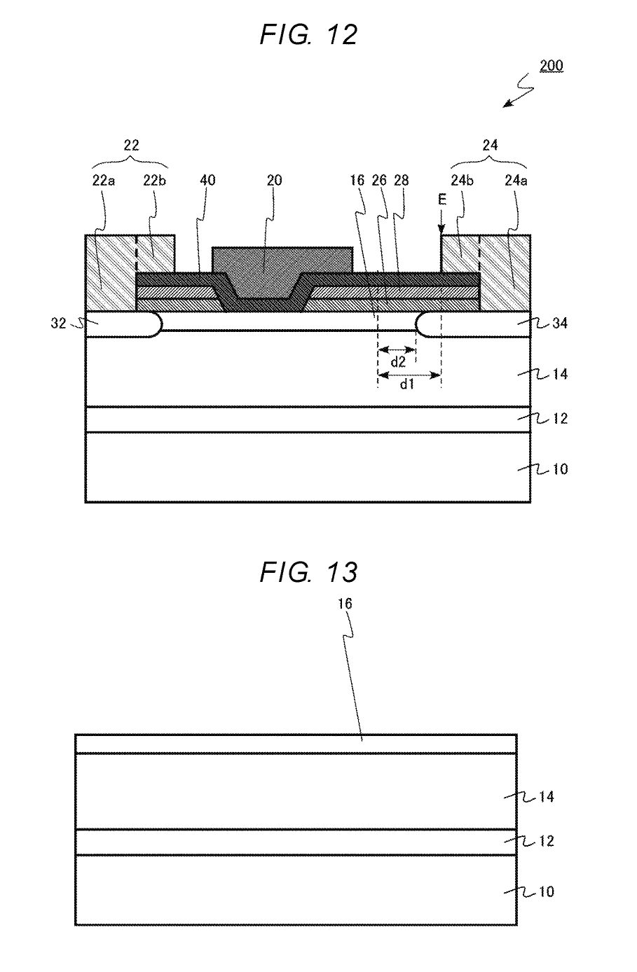

An example of a manufacturing method of the semiconductor device according to some embodiments will be described below. FIGS. 13 to 21 are schematic cross-sectional views of the semiconductor device which is being manufactured in the manufacturing method of the semiconductor device according to some embodiments. Hereinafter, the same descriptions as those of the embodiments illustrated in FIGS. 1-11 will be omitted.

First, in some embodiments, a buffer layer 12, a channel layer 14, and a barrier layer 16 are grown on the substrate 10 through epitaxial growth, for example (see FIG. 13).

Next, in some embodiments, a sacrifice film 52 is formed on the barrier layer 16. The sacrifice film 52 is formed of silicon oxide, for example. The sacrifice film 52 has a thickness of 100 nm, for example.

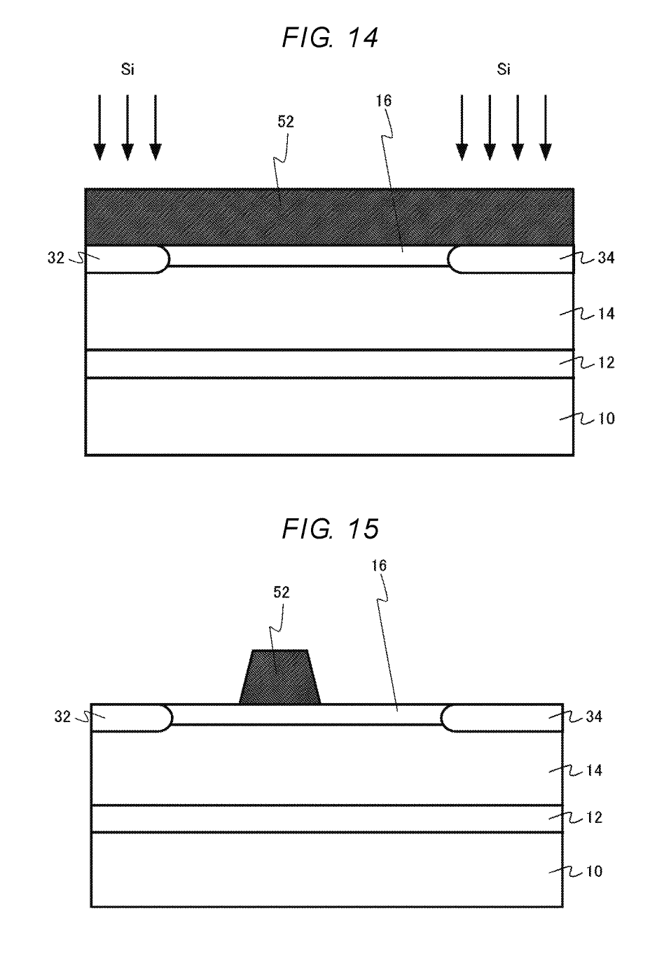

Subsequently, in some embodiments, a first n-type impurity region 32 and a second n-type impurity region 34 are formed (see FIG. 14). In some embodiments, the first n-type impurity region 32 and the second n-type impurity region 34 are formed by patterning of a photoresist according to photolithography and ion implantation of silicon, for example. In some embodiments, silicon ions are introduced to the barrier layer 16 and an upper part of the channel layer 14 through the sacrifice film 52.

Subsequently, in some embodiments, a part of the sacrifice film 52 is selectively removed (see FIG. 15). The sacrifice film 52 is removed by patterning of a photoresist according to photolithography and dry etching, for example. The dry etching is performed by ICP-RIE, for example.

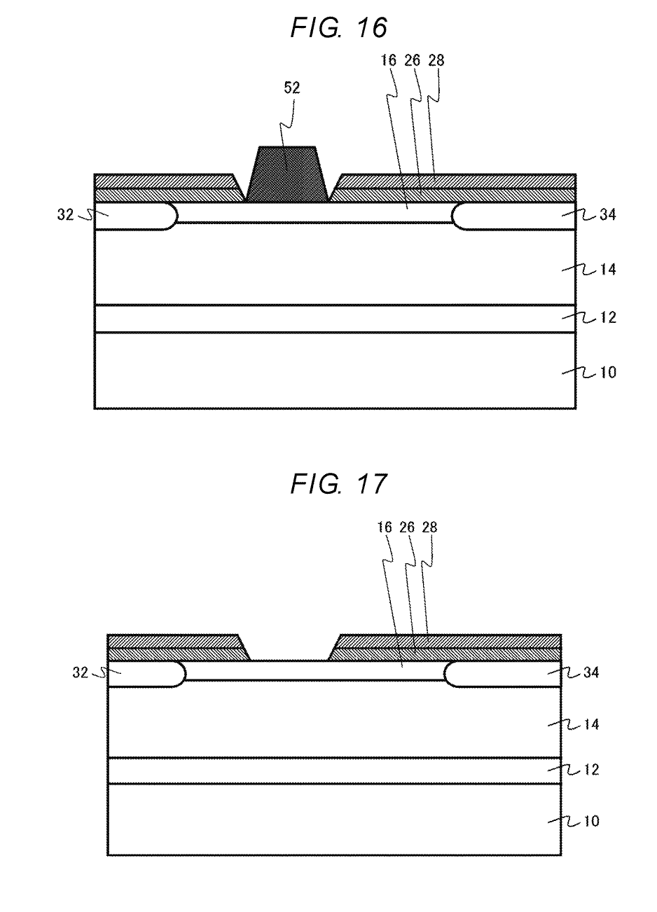

Subsequently, in some embodiments, a first aluminum nitride layer 26, a second aluminum nitride layer 28, and an aluminum oxide layer 30 are formed on the barrier layer 16 (see FIG. 16). The first aluminum nitride layer 26, the second aluminum nitride layer 28, and the aluminum oxide layer 30 are successively formed by ALD, for example.

First, in some embodiments, the first aluminum nitride layer 26 having crystalline properties is formed on the barrier layer 16. The first aluminum nitride layer 26 is a monocrystalline layer, for example. Next, in some embodiments, the second aluminum nitride layer 28 having non-crystalline properties is formed on the first aluminum nitride layer 26 by changing deposition conditions for aluminum nitride. For example, the second aluminum nitride layer 28 is formed at a lower temperature compared to the first aluminum nitride layer 26.

Subsequently, in some embodiments, the sacrifice film 52 is removed by wet etching (see FIG. 17).

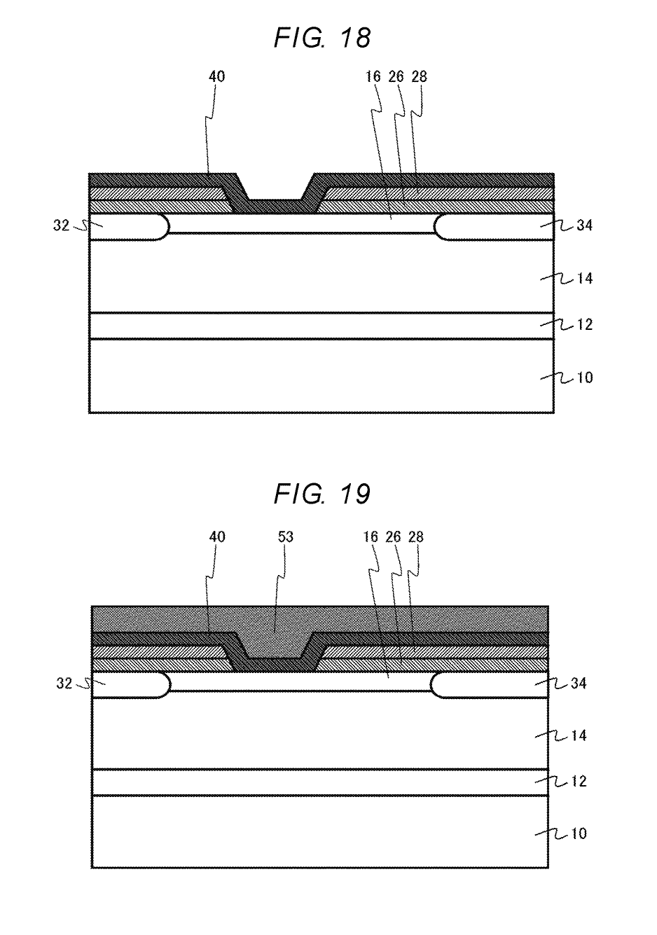

Next, in some embodiments, a gate insulation layer 40 is formed on the barrier layer 16, the first aluminum nitride layer 26, and the second aluminum nitride layer 28 (see FIG. 18). The gate insulation layer 40 is formed of silicon oxide, for example.

The gate insulation layer 40 is formed by ALD, for example. The gate insulation layer 40 has a thickness of 20 nm, for example.

Subsequently, in some embodiments, a metal film 53 to be a gate electrode 20 is formed on the gate insulation layer 40 (see FIG. 19). The metal film 53 is formed of titanium nitride, for example. For example, the metal film 53 is formed by sputtering.

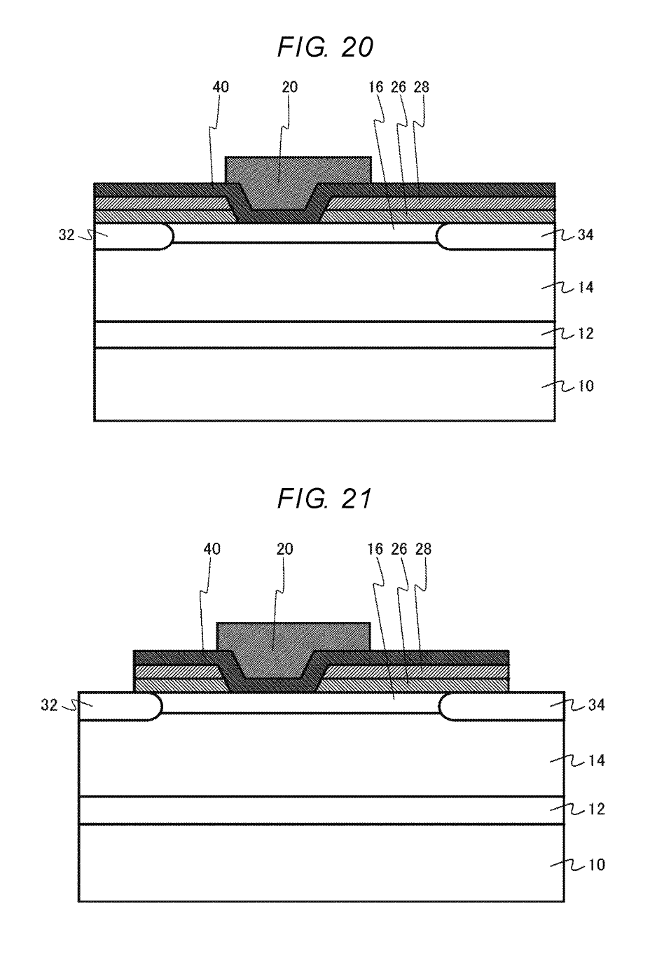

Subsequently, in some embodiments, the metal film 53 is processed to form the gate electrode 20 (see FIG. 20). In some embodiments, The gate electrode 20 is formed by patterning of a photoresist according to photolithography and dry etching, for example.

Next, in some embodiments, an opening is formed in the first aluminum nitride layer 26, the second aluminum nitride layer 28, and the gate layer 20 which are formed on the first n-type impurity region 32 and the second n-type impurity region (see FIG. 21).

Subsequently, in some embodiments, a source electrode 22 and a drain electrode 24 are formed in a region including the opening. In some embodiments, the source electrode 22 and the drain electrode 24 are formed by deposition of a stacked film of titanium (Ti)/aluminum (Al)/titanium (Ti) according to sputtering, patterning of a photoresist according to photolithography, and dry etching, for example.

By the above-described manufacturing method, the HEMT 200 is manufactured as illustrated in FIG. 12.

In some embodiments like those illustrated in FIGS. 12-21, the HEMT 200 is manufactured to be capable of realizing the low on-resistance and the normally-off operation, thereby realizing improved reliability of the HEMT 200. Further, the HEMT 200 can be realized by which the chip size is reduced and the manufacturing costs are reduced. Furthermore, in some embodiments, the gate insulation layer 40 is provided, and thus the HEMT 200 is realized in which the gate leak current can be suppressed.

In some embodiments, the gallium nitride or the aluminum gallium nitride is exemplified as the material of the nitride semiconductor layer. However, for example, indium gallium nitride, indium aluminum nitride, or indium aluminum gallium nitride containing indium (In) can also be applied. In addition, aluminum nitride can also be applied as the material of the nitride semiconductor layer.

In some embodiments, the HEMT of the junction gate structure having the p-type layer or the HEMT of a planar gate structure having the gate insulation layer and the barrier layer of a uniform thickness is exemplified as a structure of the HEMT. However, exemplary embodiments of the present disclosure can also be applied to an HEMT of another structure such as an HEMT of a Schottky gate structure, or an HEMT of a recess gate structure having a gate electrode in a recess provided in a channel layer or a barrier layer.

In the manufacturing method according to some embodiments, the dry etching of the p-type layer on the barrier layer is exemplified as the post-treatment of the present disclosure. As an example of the post-treatment, other post-treatments of dry etching, for example, recess etching for forming a recess gate structure and the like are applicable as long as the surface of the nitride semiconductor layer is exposed by dry etching.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

1. A semiconductor device comprising:
a first nitride semiconductor layer;
a second nitride semiconductor layer provided on the first nitride semiconductor layer and having a bandgap larger than a bandgap of the first nitride semiconductor layer;
a gate electrode provided on the first nitride semiconductor layer;
a first electrode provided on the first nitride semiconductor layer;
a second electrode provided on the first nitride semiconductor layer, the gate electrode being located between the first electrode and the second electrode;
a first aluminum nitride layer provided between the gate electrode and the second electrode and on the second nitride semiconductor layer;
a second aluminum nitride layer provided between the gate electrode and the second electrode and on the first aluminum nitride layer; and
a semiconductor region provided between the second electrode and the first nitride semiconductor layer and having an n-type impurity concentration higher than an n-type impurity concentration of the second nitride semiconductor layer, the semiconductor region spaced from the second nitride semiconductor layer just under the gate electrode in a first direction from the gate electrode to the second electrode.

2. The semiconductor device according to claim 1, wherein the first aluminum nitride layer is a monocrystalline layer.

3. (canceled)

4. The semiconductor device according to claim 1, wherein
the second electrode comprises a first region and a second region protruding from the first region toward the gate electrode, and
the semiconductor region is located closer to the gate electrode than the second region in the first direction.

5. The semiconductor device according to claim 1, further comprising:
a third nitride semiconductor layer provided between the second nitride semiconductor layer and the gate electrode, the third nitride semiconductor layer being a p-type layer.

6. The semiconductor device according to claim 1, further comprising:
a gate insulation layer provided between the second nitride semiconductor layer and the gate electrode.

7. The semiconductor device according to claim 1, wherein the first aluminum nitride layer has a thickness of 10 nm or less.

8. The semiconductor device according to claim 1, wherein the sum of a thickness of the first aluminum nitride layer and a thickness of the second aluminum nitride layer is 10 nm or greater.

9. The semiconductor device according to claim 1, wherein the first aluminum nitride layer and the second aluminum nitride layer are provided between the semiconductor region and the second region of the second electrode.

10. The semiconductor device according to claim 1, wherein the semiconductor region is directly in contact with the first nitride semiconductor layer.
